(19) United States
(12) Patent Application Publication
(10) Pub. No.: US 2021/0005502 A1
(43) Pub. Date: Jan. 7, 2021

(54) STAGE, SUBSTRATE PROCESSING APPARATUS AND STAGE ASSEMBLING METHOD

(71) Applicant: TOKYO ELECTRON LIMITED, Tokyo (JP)

(72) Inventors: Yuichiro WAGATSUMA, Nirasaki City (JP); Kentaro ASAKURA, Nirasaki City (JP); Tetsuya SAITOU, Nirasaki City (JP); Masahisa WATANABE, Nirasaki City (JP)

(21) Appl. No.: 16/909,228

(22) Filed: Jun. 23, 2020

(30) Foreign Application Priority Data
Jul. 5, 2019 (JP) 2019-126429

(51) Int. Cl. H01L 21/687; C23C 16/455

(52) U.S. Cl. CPC H01L 21/68735; H01L 21/68785; C23C 16/45544; H01L 21/68742

(57) ABSTRACT

A stage on which a substrate is mounted, includes a stage body having an upper surface on which the substrate is mounted, a cover member configured to cover an outer edge portion of the upper surface of the stage body, and a positional deviation preventing member provided between the upper surface of the stage body and a lower surface of the cover member and configured to roll or slide. A body-side recess configured to accommodate the positional deviation preventing member is formed on the upper surface of the stage body. A cover-side recess configured to accommodate the positional deviation preventing member accommodated in the body-side recess is formed on the lower surface of the cover member. At least one of the body-side recess and the cover-side recess is formed in a bowl shape having an inclined surface extending along a radial direction of the stage body.

### CROSS-REFERENCE TO RELATED APPLICATION

This application is based upon and claims the benefit of priority from Japanese Patent Application No. 2019-126429, filed on Jul. 5, 2019, the entire contents of which are incorporated herein by reference.

### TECHNICAL FIELD

The present disclosure relates to a stage, a substrate processing apparatus and a stage assembling method.

### BACKGROUND

In Patent Document 1, with respect to a stage provided in a chamber of a film-forming apparatus so that a semiconductor wafer (hereinafter referred to as “wafer”) is mounted thereon, there is disclosed a stage in which a cover member is provided to cover the outer edge portion of the stage and the side peripheral surface of the stage in a circumferential direction.

### PRIOR ART DOCUMENT

### Patent Document

(Patent Document 1) Japanese Patent Application Publication No. 2018-70906

### SUMMARY

According to one embodiment of the present disclosure, there is provided a stage on which a substrate is mounted, including a stage body having an upper surface on which the substrate is mounted, a cover member configured to cover an outer edge portion of the upper surface of the stage body, and a positional deviation preventing member provided between the upper surface of the stage body and a lower surface of the cover member and configured to roll or slide. A body-side recess configured to accommodate the positional deviation preventing member is formed on the upper surface of the stage body. A cover-side recess configured to accommodate the positional deviation preventing member accommodated in the body-side recess is formed on the lower surface of the cover member. At least one of the body-side recess and the cover-side recess is formed in a bowl shape having an inclined surface extending along a radial direction of the stage body.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram for explaining a problem to be addressed by the present disclosure.

FIG. 2 is an explanatory view schematically showing an outline of a configuration of a film-forming apparatus as a substrate processing apparatus according to a first embodiment.

FIG. 3 is a partially enlarged sectional view showing an internal state of the film-forming apparatus shown in FIG. 2.

FIG. 4 is a partially enlarged sectional view of a stage.

FIG. 5 is a top view of the stage body.

FIG. 6 is a bottom view of a cover member.

FIG. 7 is a plan view of a cover-side recess.

FIG. 8 is a diagram for explaining another example of the positional deviation preventing member.

FIG. 9 is a diagram for explaining another example of the positional deviation preventing member.

FIG. 10 is a diagram for explaining another example of the stage body.

FIG. 11 is an explanatory view schematically showing an outline of a configuration of a film-forming apparatus as a substrate processing apparatus according to a second embodiment.

FIG. 12 is a top view of a pin support member shown in FIG. 11.

FIG. 13 is a bottom view of a cover member shown in FIG. 11.

FIG. 14 is a side view of an engaging portion of the cover member shown in FIG. 11.

FIG. 15 is a diagram for explaining another example of the lift pin according to the second embodiment.

FIG. 16 is a diagram for explaining another example of the cover member according to the second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

For example, in a semiconductor device manufacturing process, a substrate processing process such as a film-forming process or the like is performed on a substrate such as a wafer or the like. The substrate processing process is performed using a substrate processing apparatus. A stage on which a substrate is mounted is provided in the substrate processing apparatus. As the stage, there is known a stage that includes a stage body having an upper surface on which a substrate is mounted and a cover member configured to cover an outer edge portion of the upper surface of the stage body. Furthermore, when processing the substrate, the temperature of the substrate mounted on the stage body may be adjusted by heating or cooling the stage body.

It is preferable that the positional relationship between the cover member and the stage body is constant. However, for example, when the stage body is rotated so that the substrate processing process is uniformly performed on the substrate surface, the position of the cover member may be deviated with respect to the stage body. Patent Document 1 does not disclose a technique for suppressing positional deviation of the cover member with respect to the stage body.

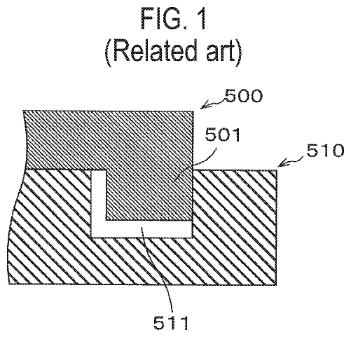

A mechanism shown in FIG. 1 is conceivable as the mechanism for suppressing the positional deviation of the cover member with respect to the stage body. The positional deviation suppressing mechanism shown in FIG. 1 has a fixing protrusion 501 integrally formed on a lower surface of a cover member 500, and a vertical hole 511 formed on an upper surface of a stage body 510. By mounting the cover member 500 so that the fixing protrusion 501 is inserted into the vertical hole 511, the positional deviation of the cover member 500 with respect to the stage body 510 is suppressed.

However, in the positional deviation suppressing mechanism shown in FIG. 1, when the stage body 510 is cooled and thermally contracted during maintenance after the heating thereof, the thermal contraction of the stage body is hindered by the fixing protrusion 501, and a thermal stress is generated in the stage body 510. As a result, damage such as a crack or the like may be generated in the stage body 510. This also holds true when the stage body 510 is thermally expanded.

The technique according to the present disclosure suppresses the positional deviation of the cover member with respect to the stage body, and prevents damage from being generated in the stage body during thermal expansion or thermal contraction of the stage body through the use of the mechanism for suppressing the positional deviation.

Hereinafter, a stage, a substrate processing apparatus and a stage assembling method according to the present embodiment will be described with reference to the drawings. In the subject specification and the drawings, elements having substantially the same functional configuration are designated by like reference numerals. The duplicate description thereof will be omitted.

### First Embodiment

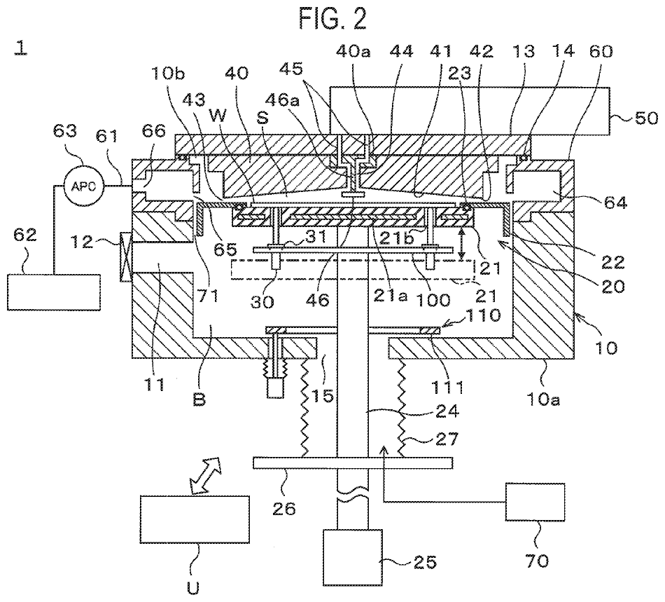

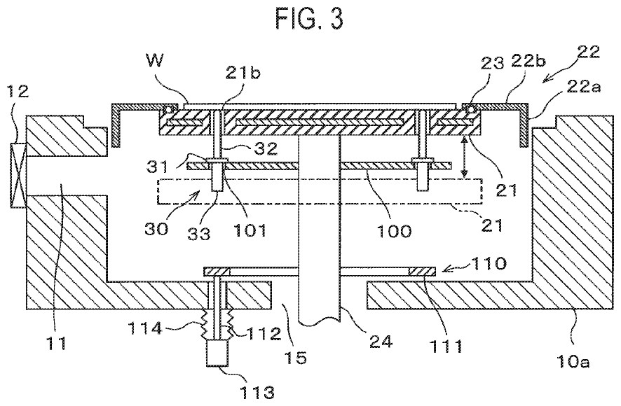

FIG. 2 is an explanatory diagram schematically showing an outline of a configuration of a film-forming apparatus as a substrate processing apparatus according to a first embodiment, and shows a part of the film-forming apparatus in cross section. FIG. 3 is a partially enlarged sectional view showing an internal state of the film-forming apparatus shown in FIG. 2. The film-forming apparatus 1 shown in FIG. 2 is configured to be depressurized and includes a processing container 10 that accommodates a wafer W as a substrate.

The processing container 10 includes a container body 10a formed in a bottom-closed cylindrical shape. A wafer loading/unloading port 11 is provided on the side wall of the container body 10a, and a gate valve 12 for opening/closing the loading/unloading port 11 is provided in the loading/unloading port 11. A below-described exhaust duct 60, which forms a part of the side wall of the container body 10a, is provided on the upper side of the loading/unloading port 11. An opening 10b is provided in the upper portion of the container body 10a, i.e., in the exhaust duct 60. A lid 13 is attached so as to close the opening 10b. An O-ring 14 for keeping the inside of the processing container 10 airtight is provided between the exhaust duct 60 and the lid 13.

A stage 20 on which the wafer W is mounted is provided in the processing container 10. The stage 20 includes a stage body 21 having an upper surface on which the wafer W is horizontally mounted. A heater 21a for heating the wafer W is provided inside the stage body 21. When the wafer W needs to be cooled, a cooling mechanism is provided inside the stage body 21. Both the heater 21a and the cooling mechanism may be provided inside the stage body 21 so that both heating and cooling of the wafer W can be performed. In addition, a plurality of through-holes 21b penetrating in the vertical direction is formed in the stage body 21. Lift pins 30 described later are inserted into the through-holes 21b.

The stage 20 also includes a cover member 22 that covers the outer edge portion of the upper surface of the stage body 21. Specifically, the cover member 22 covers the region on the outer peripheral side of the wafer mounting region of the upper surface of the stage body 21 and the side peripheral surface of the stage body 21 in the circumferential direction. The cover member 22 divides the inside of the processing container 10 into a space above the stage body 21 and a space below the stage body 21 (hereinafter referred to as bottom space B). Furthermore, the stage 20 includes balls 23 as a positional deviation preventing member provided between the upper surface of the stage body 21 and the cover member 22 and configured to roll along the upper surface of the stage body 21.

Detailed configurations of the stage body 21, the cover member 22 and the balls 23 will be described later.

An upper end of a support shaft member 24 as a table support member extending vertically through an opening 15 formed in the bottom wall of the processing container 10 is connected to the central portion of the lower surface of the stage body 21. The lower end of the support shaft member 24 is connected to a drive mechanism 25 as a moving mechanism. The drive mechanism 25 generates a drive force for moving the support shaft member 24 up and down and rotating the support shaft member 24. The drive mechanism 25 includes, for example, an air cylinder (not shown) and a motor (not shown). As the support shaft member 24 moves up and down by the driving of the drive mechanism 25, the stage body 21 may move up and down between a transfer position indicated by a two-dot chain line and a processing position above the transfer position. The transfer position refers to a position where the stage 20 waits when the wafer W is delivered between a wafer transfer mechanism moving into the processing container 10 through the loading/unloading port 11 of the processing container 10 and the lift pins 30 described later. Furthermore, the processing position refers to a position where a film-forming process is performed on the wafer W. In addition, as the support shaft member 24 is rotated about its axis by the driving of the drive mechanism 25, the stage body 21 rotates about the axis.

A flange 26 is provided in the support shaft member 24 outside the processing container 10. A bellows 27 is provided between the flange 26 and the support shaft member penetrating portion of the bottom wall of the processing container 10 so as to surround the outer peripheral portion of the support shaft member 24. Thus, the airtightness of the processing container 10 is maintained.

Furthermore, lift pins 30 as substrate support pins inserted into the above-described through-holes 21b from below are provided with respect to the stage body 21. The lift pins 30 serve to deliver the wafer W between the wafer transfer device (not shown), which is inserted into the processing container 10 from the outside of the processing container 10, and the stage 20. The lift pins 30 are configured to be able to protrude from the upper surface of the stage body 21 located at the above-described transfer position via the through-holes 21b. The lift pins 30 are provided for each through-hole 21b.

Each of the lift pins 30 is a rod-shaped member having a flange portion 31 located below the lower surface of the stage 20, and is made of, for example, alumina. The flange portion 31 is configured to lock each of the lift pins 30 to a pin support member 100 described later, and is formed, for example, at a substantially central portion of each of the lift pins 30. As shown in FIG. 3, the portion 32 of each of the lift pins 30 above the flange portion 31 is inserted into the through-hole 21b of the stage body 21. Furthermore, the portion 33 of each of the lift pins 30 below the flange portion 31 is inserted into an insertion hole 101 of a pin support member 100 described later. The through-hole 21b of the stage body 21 into which each of the lift pins 30 is inserted as described above is formed to be thinner than the flange portion 31 of each of the lift pins 30. In other words, the inner diameter of the through-hole 21b of the stage body 21 is set smaller than the diameter of the flange portion 31 of each of the lift pins 30.

Furthermore, as shown in FIG. 2, a cap member 40 for forming a processing space S between the cap member 40 and the stage body 21 is provided between the stage body 21 and the lid 13 so as to face the stage body 21. The cap member 40 is fixed to the lid 13 by bolts (not shown). An inverted bowl-shaped recess 41 is formed in the lower portion of the cap member 40. A flat rim 42 is formed on the outer portion of the recess 41. The processing space S is formed by the upper surface of the stage body 21 located at the above-described processing position and the recess 41 of the cap member 40. The height of the stage body 21 when the processing space S is formed is set so that a gap 43 is formed between the lower surface of the rim 42 of the cap member 40 and the upper surface of the cover member 22. For example, the recess 41 is formed so that the volume of the processing space S becomes as small as possible and the gas replacement property at the time of replacing a processing gas with a purge gas becomes good.

A gas introduction path 44 for introducing a processing gas or a purge gas into the processing space S is formed at the central portion of the cap member 40. The gas introduction path 44 penetrates through the central portion of the cap member 40. The gas introduction path 44 is provided so that the lower end thereof faces the central portion of the wafer W mounted on the stage 20. A flow path forming member 40a is fitted into the central portion of the cap member 40. The upper side of the gas introduction path 44 is branched by the flow path forming member 40a. Each of the branches communicates with the gas introduction path 45 that penetrates through the lid 13. Below the lower end of the gas introduction path 44 of the cap member 40, there is provided a dispersion plate 46 for dispersing the gas discharged from the gas introduction path 44 into the processing space S. The dispersion plate 46 is fixed to the cap member 40 via a support rod 46a.

In the gas introduction path 45, there is provided a gas introduction mechanism 50 that introduces a TiCl₄ gas or an NH₃ gas as a processing gas and an N₂ gas as a purge gas g, and the like into the processing container 10 from gas supply sources (not shown). An O-ring (not shown) for keeping the inside of the processing container 10 airtight is provided between the gas introduction mechanism 50 and the processing container 10, specifically between the gas introduction mechanism 50 and the lid 13.

Furthermore, one end of an exhaust pipe 61 is connected to the exhaust duct 60 of the container body 10a. The other end of the exhaust pipe 61 is connected to an exhaust device 62 configured by, for example, a vacuum pump. Furthermore, an APC valve 63 for adjusting the pressure in the processing space S is provided upstream of the exhaust device 62 in the exhaust pipe 61.

The exhaust duct 60 is configured to annularly form a gas passage 64 having a rectangular vertical cross section. A slit 65 is formed on the inner circumferential surface of the exhaust duct 60 over the entire circumference. An exhaust port 66 is provided on the outer wall of the exhaust duct 60, and the exhaust pipe 61 is connected to the exhaust port 66. The slit 65 is formed at a position corresponding to the aforementioned gap 43 formed when the stage 20 is raised to the aforementioned processing position. Therefore, by operating the exhaust device 62, the gas in the processing space S is moved to the gas passage 64 of the exhaust duct 60 through the gap 43 and the slit 65, and is exhausted through the exhaust pipe 61.

Furthermore, for the processing container 10, there is provided an additional gas introduction mechanism 70 for introducing a bottom purge gas into the aforementioned bottom space B. The bottom purge gas is a gas for preventing the processing gas supplied to the processing space S from flowing into the bottom space B. For example, an inert gas such as an N₂ gas or the like is used as the bottom purge gas. Furthermore, the bottom purge gas is introduced into the bottom space B via, for example, a gas introduction hole (not shown) provided in the flange 26. The bottom purge gas introduced into the bottom space B is moved to the exhaust duct 60 through a gap 71 between the cover member 22 and the side wall of the processing container 10 and is discharged from the exhaust duct 60.

Furthermore, in the film-forming apparatus 1, a pin support member 100 as a member configured to support the lift pins 30 and a pin moving mechanism 110 configured to support the lift pins 30 while moving the supported lift pins 30 in the vertical direction are provided with respect to the lift pins 30.

Specifically, the pin support member 100 supports the lift pins 30 from below so as to be movable in the vertical direction, i.e., in the up-down direction, by engaging with the flange portions 31 of the lift pins 30. More specifically, as shown in FIG. 3, insertion holes 101 into which the portions 33 of the lift pins 30 below the flange portions 31 are inserted and which has an inner diameter larger than the outer diameter of the portions 33 are formed in the pin support member 100. The pin support member 100 is configured to suspend the lift pins 30 by bringing the upper surface around the insertion holes 101 of the pin support member 100 into contact with the lower surfaces of the flange portions 31 of the lift pins 30 inserted into the insertion holes 101. Furthermore, with the above-described configuration, the lift pins 30 may slide along the upper surface of the pin support member 100 extending in the horizontal direction in a state in which the portions 33 of the lift pins 30 below the flange portions 31 of the lift pins 30 are inserted into the insertion holes 101. The lift pins 30 may move in the horizontal direction along the upper surface of the pin support member 100 within a range defined by the portions 33 below the flange portions 31 and the insertion holes 101 while being supported by the pin support member 100.

Furthermore, the pin support member 10 is fixed with respect to the stage body 21. Specifically, the pin support member 100 is attached to, for example, the support shaft member 24 connected to the stage body 21. Therefore, the pin support member 100 is vertically moved together with the stage body 21 by the drive mechanism 25, and is also rotated together with the stage body 21. The pin support member 100 is formed of, for example, a plate-shaped member having an annular shape in a plan view and made of a low thermal conductivity material such as alumina or quartz.

The pin moving mechanism 110 supports the lift pins 30 from below by engaging with the lower end portions of the lift pins 30. Specifically, the pin moving mechanism 110 includes a contact member 111, and supports the lift pins 30 as the lower end surfaces of the lift pins 30 inserted into the insertion holes 101 of the pin support member 100 and exposed from the lower surface of the pin support member 100 come into contact with the upper surface of the contact member 111. The contact member 111 is formed of, for example, a member having an annular shape in a plan view.

A support column 112 is provided on the lower surface side of the contact member 111. The support column 112 penetrates the bottom wall of the processing container 10. The support column 112 is connected to a drive mechanism 113 provided outside the processing container 10. The drive mechanism 113 generates a driving force for moving the support column 112 up and down. As the support column 112 is moved up and down by the driving of the drive mechanism 113, the contact member 111 moves up and down, whereby the lift pins 30 supported by the contact member 111 can move up and down independently of the stage body 21. In particular, as the support column 112 is moved upward by the driving of the drive mechanism 113, the lift pins 30 move upward, so that the upper end portions of the lift pins 30 protrude from the upper surface of the stage 20 moved to the transfer position.

A bellows 114 is provided between the drive mechanism 113 and the support column penetration portion of the support column of the bottom wall of the processing container 10 so as to surround the outer periphery of the support column 112. Thus, the airtightness of the processing container 10 is maintained.

The film-forming apparatus 1 configured as described above is provided with a controller U as shown in FIG. 2. The controller U is formed of, for example, a computer including a CPU and a memory. The controller U includes a program storage part (not shown). The program storage part stores a program or the like for realizing below-described wafer processing in the film-forming apparatus 1. The program may be recorded in a non-transitory computer-readable storage medium, and may be installed in the controller U from the storage medium. In addition, the program may be partly or entirely realized by dedicated hardware (circuit board).

Now, the wafer processing performed using the film-forming apparatus 1 will be described. First, the gate valve 12 is opened, and the wafer transfer device (not shown) holding the wafer W is moved into the processing container 10 from the vacuum-atmosphere transfer chamber (not shown) adjacent to the processing container 10 via the loading/unloading port 11. Then, the wafer W is transferred to above the stage body 21 that has been moved to the standby position. Then, the lift pins 30 suspended by the pin support member 100 are lifted by the pin moving mechanism 110. As a result, the suspension is released, the lift pins 30 protrude from the upper surface of the stage body 21 by a predetermined distance, and the wafer W is delivered onto the lift pins 30. Thereafter, the wafer transfer device is moved out of the processing container 10, and the gate valve 12 is closed. At the same time, the lift pins 30 are lowered by the pin moving mechanism 110, and the stage body 21 is raised by the drive mechanism 25. As a result, the support of the lift pins 30 by the pin moving mechanism 110 is released, and the lift pins 30 are suspended again by the pin support member 100. The upper end portions of the lift pins 30 are accommodated in the through-holes 21b of the stage body 21 and do not protrude from the upper surface of the stage body 21. The wafer W is mounted on the stage body 21. Then, the inside of the processing container 10 is adjusted to a predetermined pressure, the stage body 21 is moved to the processing position by the drive mechanism 25, and the processing space S is formed.

In this state, an N₂ gas as a purge gas is supplied to the processing space S via the gas introduction mechanism 50, and a TiCl₄ gas and an NH₃ gas are alternately and intermittently supplied to the processing space S, whereby a TiN film is formed on the wafer W by an ALD method. During this film formation, the wafer W is heated by the stage body 21. For example, the temperature of the wafer W (specifically, the temperature of the stage body 21) is set to 300 degrees C. to 600 degrees C.

After the TiN film is formed by the ALD method as described above, the stage body 21 on which the wafer W is mounted is lowered to the transfer position. Next, the lift pins 30 are raised by the pin moving mechanism 110. As a result, the suspension of the lift pins 30 by the pin support member 100 is released, the lift pins 30 protrude from the upper surface of the stage body 21 by a predetermined distance, and the wafer W is delivered onto the lift pins 30. Thereafter, the gate valve 12 is opened, and the wafer transfer device that does not hold the wafer W is moved into the processing container 10 via the loading/unloading port 11. The wafer transfer device is moved between the wafer W held on the lift pins 30 and the stage body 21 located at the transfer position. Then, the lift pins 30 are lowered by the pin moving mechanism 110, and the wafer W on the lift pins 30 is delivered to the wafer transfer device. Then, the wafer transfer device is moved out of the processing container 10, and the gate valve 12 is closed. Thus, a series of wafer processing processes are completed. Thereafter, the above-described series of wafer processing processes are performed on other wafers W.

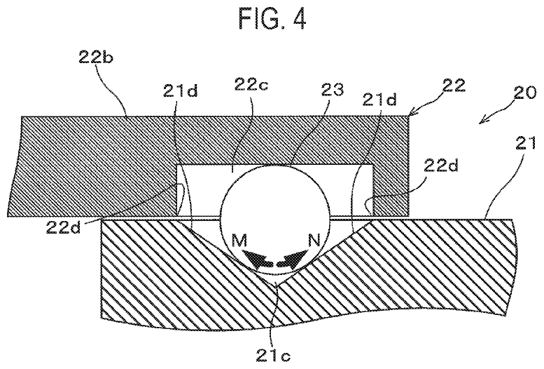

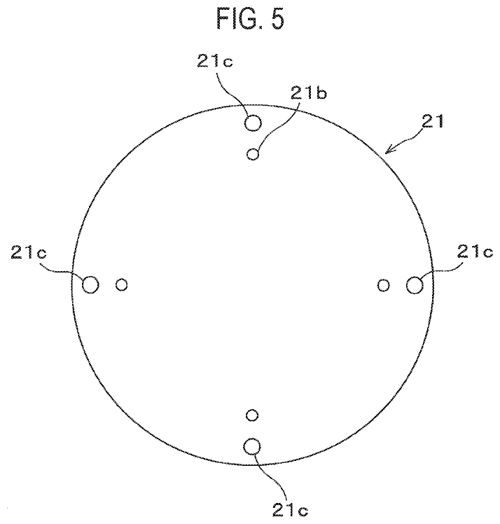

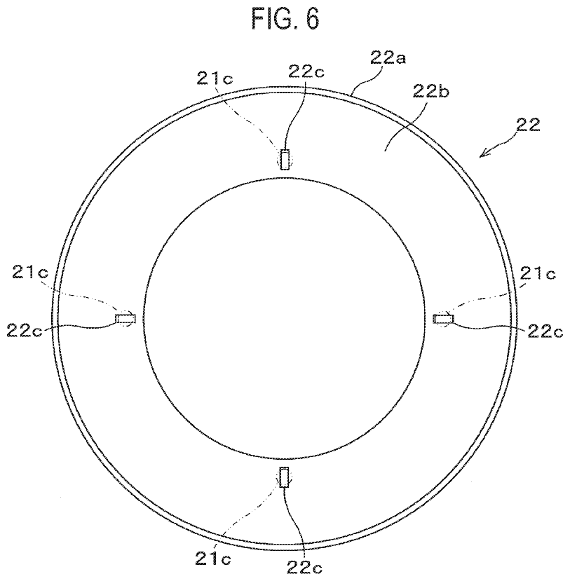

Next, the stage body 21, the cover member 22 and the balls 23 included in the stage 20 will be described with reference to FIG. 3 and FIGS. 4 to 7. FIG. 4 is a partially enlarged sectional view of the stage 20, FIG. 5 is a top view of the stage body 21, FIG. 6 is a bottom view of the cover member 22, and FIG. 7 is a plan view of a cover-side recess described later.

As shown in FIG. 4, body-side recesses 21c for accommodating the balls 23 are formed on the upper surface of the stage body 21. Specifically, the body-side recesses 21c accommodate the lower sides of the balls 23. Each of the body-side recesses 21c is formed in a bowl shape having an inclined surface 21d extending along the radial direction of the stage body 21. Specifically, the body-side recesses 21c are formed so as to be recessed in a conical shape. For example, as shown in FIG. 5, a plurality of (four, in the example of FIG. 4) body-side recesses 21c are formed along the circumferential direction. The stage body 21 is made of, for example, alumina, and is integrally formed with the support shaft member 24.

As shown in FIG. 3, the cover member 22 is formed in a cylindrical shape having open upper and lower ends. The cover member 22 has a flow path forming portion 22a that extends along the side wall of the processing container 10 and forms a flow path for a bottom purge gas between the side wall and the flow path forming portion 22a, and has an engaging portion 22b extending horizontally inward along the circumferential direction of the upper end of the flow path forming portion 22a. The engaging portion 22b is engaged with the upper surface of the stage body 21. The engaging portion 22b is formed to have a thickness larger than that of the wafer W.

As shown in FIG. 4, cover-side recesses 22c for accommodating the balls 23 are formed on the lower surface of the cover member 22. Specifically, the cover-side recesses 22c are formed on the lower surface of the engaging portion 22b to accommodate the upper portions of the balls 23. The cover-side recesses 22c are formed to have, for example, a rectangular cross-sectional shape. Furthermore, as shown in FIG. 6, for example, the cover-side recesses 22c are formed in a rectangular shape so as to be elongated in the radial direction in a plan view. Moreover, the cover-side recesses 22c are provided in the same number as the body-side recesses 21c, and are provided at positions corresponding to the body-side recesses 21c. The cover member 22 is made of, for example, alumina or quartz.

The balls 23 provided between the stage body 21 and the cover member 22 described above are not fixed to either the stage body 21 or the cover member 22, and are configured to roll along the inclined surfaces 21d of the body-side recesses 21c. In addition, the balls 23 are formed in a true spherical shape using, for example, alumina or quartz.

When assembling the stage 20, the stage body 21 and the cover member 22 are assembled so that one side portions of the balls 23 are accommodated in the body-side recesses 21c of the stage body 21 and the other side portions of the balls 23 are accommodated in the cover-side recesses 22c of the cover member 22. Specifically, for example, the lower portions of the balls 23 are first accommodated in the body-side recesses 21c on the upper surface of the stage body 21. Next, the cover member 22 is assembled to the stage body 21 so that the upper portions of the balls 23 accommodated in the body-side recesses 21c are accommodated in the cover-side recesses 22c on the lower surface of the cover member 22. By assembling the stage 20 as described above, it is possible to prevent the position of the cover member 22 from being deviated with respect to the stage body 21 when the stage body 21 is rotated.

In order to suppress the positional deviation in the above-described method, when the stage body 21 is thermally contracted during a temperature lowering process, the balls 23 are rotated along with the thermal contraction as indicated by an arrow M or an arrow N in FIG. 4, and can move, i.e., roll along the inclined surfaces 21d of the body-side recesses 21c. Since the thermal contraction is not hindered by the balls 23, no thermal stress is applied to the stage body 21 during the thermal contraction, or the thermal stress applied to the stage body 21 is small. Therefore, damage such as a crack or the like does not occur on the stage body 21. The same applies to the case where the stage body 21 expands during a temperature raising process.

As shown in FIG. 7, the radial length L1 of the cover-side recesses 22c in a plan view is larger than the diameter R of the balls 23. This is to prevent the lower end portions 22d (see FIG. 4) of the radial side walls of the cover-side recesses 22c from impeding the rolling of the balls 23 along the radial direction due to the thermal contraction and thermal expansion of the stage body 21.

The circumferential length L2 of the cover-side recesses 22c in a plan view is substantially equal to the diameter R of the balls 23 or smaller than the diameter R of the balls 23. This is to ensure that the movement of the cover member 22 in the circumferential direction with respect to the stage body 21, i.e., the rotation of the cover member 22 with respect to the stage body 21, is prevented by the engagement of the balls 23 with the circumferential side walls that forms the cover-side recesses 22c. As a result, it is possible to accurately prevent the positional deviation of the cover member 22 with respect to the stage body 21.

As described above, in the present embodiment, the stage 20 on which the wafer W is mounted includes the stage body 21 having an upper surface on which the wafer W is mounted, the cover member 22 configured to cover the outer edge portion of the upper surface of the stage body 21, and the balls 23 provided between the upper surface of the stage body 21 and the lower surface of the cover member 22. Furthermore, the body-side recesses 21c for accommodating the balls 23 are formed on the upper surface of the stage body 21, and the cover-side recesses 22c for accommodating the balls 23 accommodated in the body-side recesses 21c are formed on the lower surface of the cover member 22. Therefore, the positional deviation of the cover member 22 with respect to the stage body 21 can be suppressed by assembling the stage body 21 and the cover member 22 so that the one side portions of the balls 23 are accommodated in the body-side recesses 21c and the other side portions of the balls 23 are accommodated in the cover-side recesses 22c. In particular, the above positional deviation can be suppressed during the rotation of the stage body 21. Since the positional deviation can be suppressed, it is possible to prevent dust from being generated due to the positional deviation and to prevent the stage body 21 and the cover member 22 from being scratched due to the positional deviation. Furthermore, in the present embodiment, the body-side recesses 21c are formed in a bowl shape, specifically in a conical shape, so as to have the inclined surfaces 21d extending along the radial direction of the stage body 21. Therefore, the balls 23 can roll along the inclined surfaces 21d along with the thermal contraction or thermal expansion of the stage body 21 in the temperature lowering process or the temperature raising process. Accordingly, at the time of the thermal contraction and the thermal expansion, damage such as a crack or the like does not occur in the stage body 21. Furthermore, even when a deposit is deposited on the body-side recesses 21c or the cover-side recesses 22c in the film-forming process, the allowable value until the movement of the balls 23 is obstructed by the deposit is significantly larger than that of the positional deviation suppressing mechanism shown in FIG. 1. Therefore, even in this case, damage such as a crack or the like does not occur in the stage body 21.

In the present embodiment, four sets of the body-side recesses 21c, the cover-side recesses 22c and the balls 23 are provided. By providing three or more sets of the body-side recesses 21c, the cover-side recesses 22c and the balls 23 in this manner, the cover member 22 and the stage body 21 can be kept concentric. When the cover member 22 is eccentric with respect to the stage body 21, the size of the gap 71 (see FIG. 2) between the cover member 22 and the side wall of the processing container 10 becomes uneven in the circumferential direction. Therefore, the amount of the bottom purge gas flowing into the space above the stage body 21 partitioned by the cover member 22 becomes uneven in the circumferential direction. As a result, the exhaust of the processing gas from the processing space S may become non-uniform in the circumferential direction, and the film-forming process may become non-uniform in the wafer plane. This non-uniformity of the film-forming process in the wafer plane can be eliminated by making the cover member 22 and the stage body 21 concentric as described above. The body-side recesses 21c and the cover-side recesses 22c are provided so that, when the balls 23 are located at the lowest points in the body-side recesses 21c, the cover member 22 and the stage body 21 assembled together are concentric.

Furthermore, in the present embodiment, the flange portion 31 is provided in each of the lift pins 30 below the lower surface of the stage body 21, and the pin support member 100 engages with the flange portion 31 of each of the lift pins 30 to support each of the lift pins 30 so that each of the lift pins 30 can move in the horizontal direction. That is, the lift pins 30 are not fixed to the pin support member 100 or the like. Therefore, the lift pins 30 are not damaged or the smooth lifting operation of the lift pins 30 is not impaired due to the thermal expansion of the stage body 21 or the like. Furthermore, in the present embodiment, the through-holes 21b (especially the upper end portions thereof) of the stage body 21 through which the lift pins 30 are inserted are formed to be thinner than the flange portions 31 of the lift pins 30. Therefore, according to the present embodiment, the diameter of the portions corresponding to the through-holes 21b can be made small as compared with, for example, a conventional configuration in which the lift pins are suspended on the mounting surface side of the stage body 21. Accordingly, it is possible to suppress a decrease in the temperature of the portions of the wafer W corresponding to the through-holes 21b, thereby making it possible to improve the in-plane uniformity of the temperature of the wafer W.

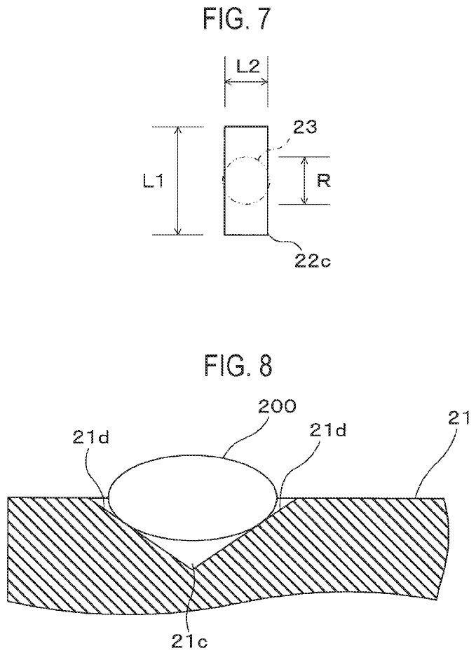

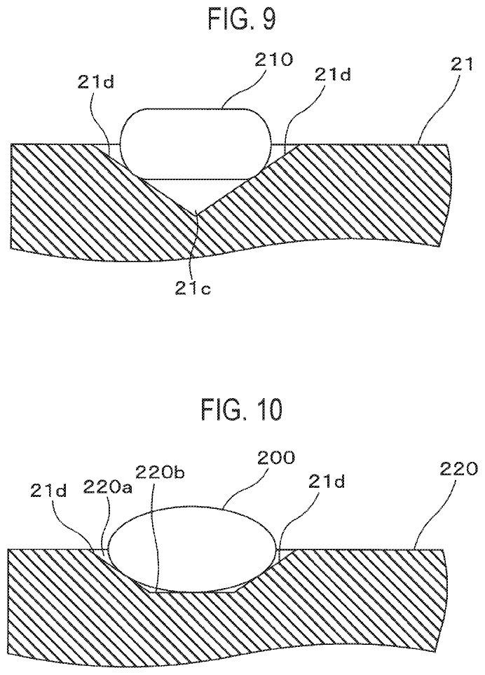

FIGS. 8 and 9 are views for explaining other examples of the positional deviation preventing member. In the above example, the positional deviation preventing member is the balls 23 formed in a true spherical shape. However, the shape of the positional deviation preventing member is not limited thereto. The positional deviation preventing member needs only to have a curved surface that comes into contact with the inclined surface 21d of each of the body-side recesses 21c when the stage body 21 thermally contracted or expanded. Therefore, for example, the positional deviation preventing member may be formed in an ellipsoidal shape like the positional deviation preventing member 200 shown in FIG. 8. In addition, the positional deviation preventing member may be formed in a rounded rectangular shape in a side view like the positional deviation preventing member 210 shown in FIG. 9.

In addition, when the positional deviation preventing member is formed into an ellipsoidal shape or a rounded rectangular side view shape as shown in FIGS. 8 and 9, the positional deviation preventing member may slide along the inclined surfaces 21d of the body-side recesses 21c instead of rolling along the inclined surfaces 21d of the body-side recesses 21c. Even in this case, the thermal contraction or thermal expansion of the stage body 21 in the temperature lowering process or the temperature raising process is not hindered by the positional deviation preventing member. Therefore, the stage body 21 does not undergo damage such as a crack or the like during the thermal contraction or thermal expansion.

FIG. 10 is a diagram for explaining another example of the stage body. In the above-described example, the bottom surface of each of the body-side recesses 21c formed on the upper surface of the stage body 21 is a concave surface. However, the shape of the body-side recesses formed on the stage body is not limited thereto. For example, the bottom surface 220b may be a flat surface like the body-side recessed portion 220a formed in the stage body 220 shown in FIG. 10.

Even when the true spherical balls 23 shown in FIG. 4 and the like or the positional deviation preventing member 210 having a rounded rectangular shape in a side view as shown in FIG. 9 is used, the bottom surface 220b of each of the body-side recesses may be formed as a flat surface.

### Second Embodiment

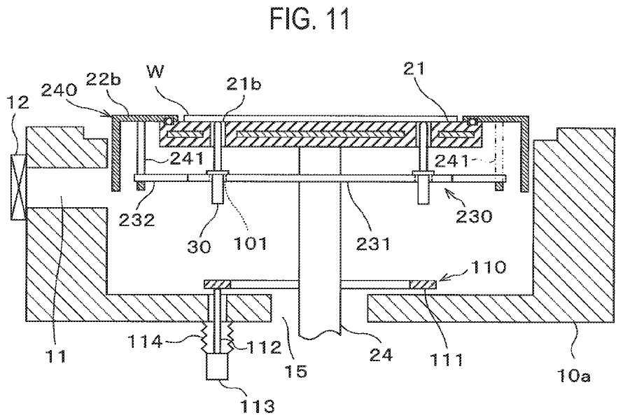

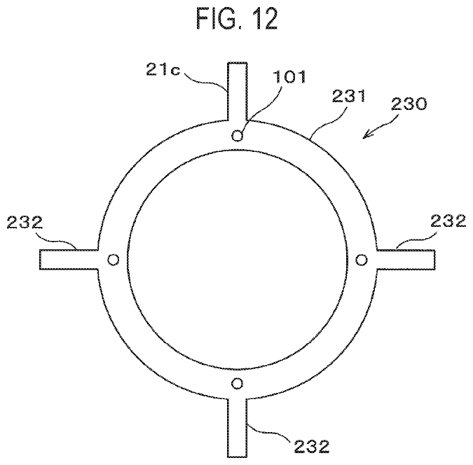

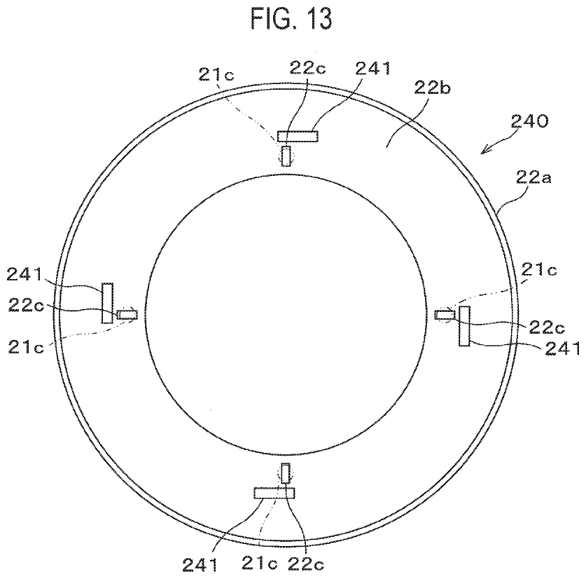

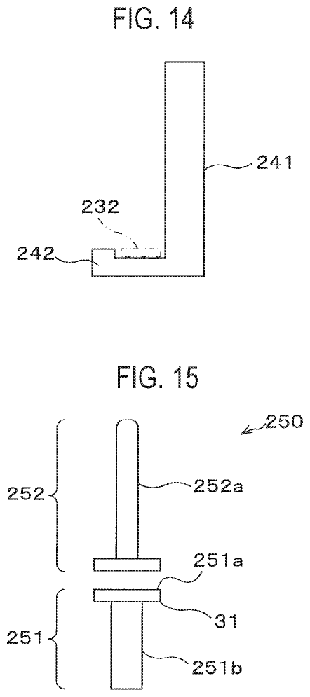

FIG. 11 is an explanatory diagram schematically showing an outline of a configuration of a film-forming apparatus as a substrate processing apparatus according to a second embodiment, and is a partially enlarged sectional view showing an internal state of the film-forming apparatus. FIG. 12 is a top view of a pin support member shown in FIG. 11. FIG. 13 is a bottom view of a cover member shown in FIG. 11. FIG. 14 is a side view of a later-described engaging portion of the cover member shown in FIG. 11.

In the first embodiment, the pin support member 100 is attached to the support shaft member 24. On the other hand, in the present embodiment, as shown in FIG. 11, the pin support member 230 is attached to the cover member 240.

As shown in FIGS. 11 and 12, the pin support member 230 includes a main body 231 having an annular shape in a plan view and having insertion holes 101 into which the lift pins 30 are inserted, and a plurality of tongue portions 232 extending outward from the main body 231. Furthermore, as shown in FIGS. 11 and 13, the cover member 240 includes a plurality of claw portions 241 formed so as to extend downward from the engaging portion 22b. The claw portions 241 are formed in, for example, an L shape in a side view as shown in FIG. 14. The pin support member 230 is attached to the cover member 240 by the engagement between the tongue portions 232 of the pin support member 230 and the lower ends 242 of the claw portions 241 of the cover member 240.

In the case of the structure in which the pin support member 230 is attached to the cover member 240 as described above, if the position of the cover member 240 deviates in the circumferential direction with respect to the stage body 21 when the stage body 21 rotates, the lift pins 30 may be broken. However, in the present embodiment, the body-side recesses 21c, the cover-side recesses 22c and the balls 23 are provided, and the positional deviation in the circumferential direction of the cover member 240 with respect to the stage body 21 is zero or small. Therefore, the lift pins 30 are not broken. Further, as compared with the configuration in which the pin support member 100 is attached to the support shaft member 24, the configuration in which the pin support member 230 is attached to the cover member 240 requires fewer changes from the conventional structure of the stage 20.

FIG. 15 is a diagram for explaining another example of the lift pins according to the second embodiment. Each of the lift pins 30 shown in FIG. 2 and the like is an integral body in which the flange portion 31 is integrally formed. On the other hand, each of the lift pins 250 shown in FIG. 15 is not an integral body but includes a plurality of members. Specifically, each of the lift pins 250 includes a first member 251 having a flange portion 31, and a second member 252 provided separately from the first member 251 and having an insertion portion 252a inserted into each of the through-holes 21b of the stage body 21. The first member 251 has a sliding surface 251a on which the second member 252 is placed and which slidably supports the second member 252. In other words, the first member 251 supports the second member 252 from below by the sliding surface 251a so that the second member 252 can slide along the sliding surface 251a. In this example, the upper end surface of the first member 251 including the upper end surface of the flange portion 31 serves as the sliding surface 251a. Furthermore, in the first member 251, an insertion portion 251b below the flange portion 31 is formed in a rod shape, and the insertion portion 251b is inserted into each of the insertion holes 101 of the pin support member 100.

By using the lift pins 250, even if the stage body 21 and the pin support member 230 are position-deviated in the radial direction when the stage body 21 is thermally contracted or expanded, the lift pins 250 are harder to be broken than the lift pins 30. When the stage body 21 is rotated and the positional deviation between the stage body 21 and the cover member 240 in the circumferential direction is large, the second member 252 of each of the lift pins 250 falls into the processing container 10. However, in the present embodiment, the body-side recesses 21c, the cover-side recesses 22c and the balls 23 are provided, and the positional deviation in the circumferential direction of the cover member 240 with respect to the stage body 21 is zero or small. Therefore, the second member 252 of each of the lift pins 250 does not fall.

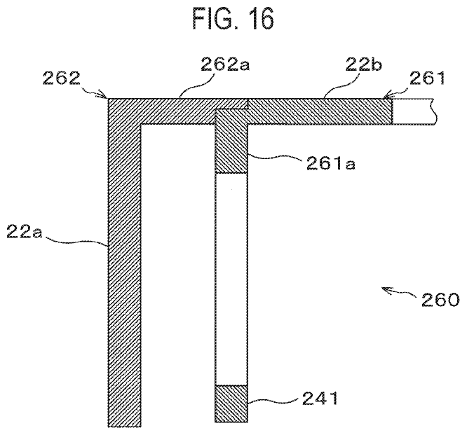

FIG. 16 is a diagram for explaining another example of the cover member according to the second embodiment. The cover member 240 in the example of FIGS. 11 and 13 is an integral body in which the flow path forming portion 22a, the engaging portion 22b and the claw portion 241 are integrally formed. On the other hand, the cover member 260 shown in FIG. 16 is not an integral body but includes a plurality of members. Specifically, the cover member 260 includes an inner member 261 having an engaging portion 22b and a claw portion 241, and an outer member 262 provided separately from the inner member 261 and having a flow path forming portion 22a.

The inner member 261 includes an annular portion 261a formed in an annular shape on the lower surface of the outer end of the engaging portion 22b. A claw portion 241 is formed below the annular portion 261a. The outer member 262 includes an engaging portion 262a that extends horizontally inward along the circumferential direction of the upper end of the flow path forming portion 22a. The engaging portion 262a is engaged and fixed on the upper surface of the inner member 261.

By providing the inner member 261 and the outer member 262 as separate bodies in this manner, it is possible to easily manufacture the cover member 260.

The outer member 262 is attached to the inner member 261 so as not to undergo positional deviation. As a mechanism for this attachment, the above-described mechanism for attaching the cover member to the stage may be used.

In the above example, the body-side recesses are formed in a bowl shape. Alternatively, the cover-side recesses may be formed in a bowl shape. Both the body-side recesses and the cover-side recesses may be formed in a bowl shape.

In the above-described embodiments, the cover member that divides the inside of the processing container 10 into the space above the stage body 21 and the bottom space B is used as the cover member. The technique according to the present disclosure may be applied to a case where a cover member different from the cover member that covers the outer edge portion of the upper surface of the stage body 21 is used. For example, there may be a case where a member that covers the entire upper surface of the stage body 21 is used in order to prevent the material (e.g., nickel) constituting the stage body from adhering to the wafer W. The technique according to the present disclosure may also be applied to this case.

Although the film formation is performed by the ALD method in the above description, the technique according to the present disclosure may be applied to a case where the film formation is performed by a CVD method. For example, the technique according to the present disclosure may be applied to a case of forming a Si film or a SiN film by a CVD method using a Si-containing gas.

Although the film-forming apparatus has been described above as an example, the technique according to the present disclosure may also be applied to a substrate processing apparatus that includes a stage and performs a process other than the film-forming process. For example, the technique according to the present disclosure may also be applied to an apparatus that performs an etching process.

The embodiments disclosed herein are to be considered as illustrative and not limitative in all respects. The above-described embodiments may be omitted, replaced or modified in various forms without departing from the scope and spirit of the appended claims.

The following configurations also belong to the technical scope of the present disclosure.

(1). A stage on which a substrate is mounted, including:
a stage body having an upper surface on which the substrate is mounted;
a cover member configured to cover an outer edge portion of the upper surface of the stage body; and
a positional deviation preventing member provided between the upper surface of the stage body and a lower surface of the cover member and configured to roll or slide,
wherein a body-side recess configured to accommodate the positional deviation preventing member is formed on the upper surface of the stage body,
a cover-side recess configured to accommodate the positional deviation preventing member accommodated in the body-side recess is formed on the lower surface of the cover member, and
at least one of the body-side recess and the cover-side recess is formed in a bowl shape having an inclined surface extending along a radial direction of the stage body.

According to the above (1), by assembling the stage body and the cover member with each other so that one side portion of the positional deviation preventing member is accommodated in the body-side recess and the other side portion of the positional deviation preventing member is accommodated in the cover-side recess, it is possible to suppress positional deviation of the cover member with respect to the stage body. In particular, it is possible to suppress positional deviation when the stage body rotates. Furthermore, since the body-side recess is formed in the bowl shape having the inclined surface extending along the radial direction of the stage body, the positional deviation preventing member can roll along the inclined surface as the stage body is thermally contracted or thermally expanded. Accordingly, damage such as a crack or the like does not occur in the stage body during the above-described thermal contraction or thermal expansion.

(2). The stage of (1), wherein the positional deviation preventing member has a curved surface that makes contact with the inclined surface.

(3). The stage of (1) or (2), wherein the positional deviation preventing member is configured to roll or slide along the inclined surface.

(4). The stage of any one of (1) to (3), wherein the positional deviation preventing member has a true spherical shape, an ellipsoidal shape, or a rounded rectangular shape in a side view.

(5). A substrate processing apparatus including the stage of any one of (1) to (4).

(6). The apparatus of (5), wherein through-holes vertically penetrate the stage body, and the apparatus further comprises:
substrate support pins inserted through the through-holes and configured to be able to protrude from the upper surface of the stage body through the through-holes; and
a pin support member configured to be able to support the substrate support pins,
wherein the pin support member is attached to the cover member.

(7). The apparatus of (5) or (6), further comprising:
a processing container in which the stage is arranged,
wherein the cover member is configured to divide an inside of the processing container into a space above the stage body and a space below the stage body.

(8). A stage assembling method for assembling a stage on which a substrate is mounted,
wherein the stage includes a stage body having an upper surface on which the substrate is mounted, a cover member configured to cover an outer edge portion of the upper surface of the stage body, and a positional deviation preventing member provided between the upper surface of the stage body and a lower surface of the cover member and configured to roll or slide,
a body-side recess configured to accommodate the positional deviation preventing member is formed on the upper surface of the stage body,
a cover-side recess configured to accommodate the positional deviation preventing member accommodated in the body-side recess is formed on the lower surface of the cover member, and
at least one of the body-side recess and the cover-side recess is formed in a bowl shape having an inclined surface extending along a radial direction of the stage body,
the method comprising:
assembling the stage body and the cover member with each other so that one side portion of the positional deviation preventing member is accommodated in the body-side recess of the stage body and an other side portion of the positional deviation preventing member is accommodated in the cover-side recess of the cover member.

According to the present disclosure in some embodiments, by a mechanism for suppressing the positional deviation, it is possible to suppress positional deviation of a cover member with respect to a stage body and to prevent damage from being generated in the stage body during thermal expansion or contraction of the stage body.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A stage on which a substrate is mounted, comprising:
a stage body having an upper surface on which the substrate is mounted;
a cover member configured to cover an outer edge portion of the upper surface of the stage body; and
a positional deviation preventing member provided between the upper surface of the stage body and a lower surface of the cover member and configured to roll or slide,
wherein a body-side recess configured to accommodate the positional deviation preventing member is formed on the upper surface of the stage body,
a cover-side recess configured to accommodate the positional deviation preventing member accommodated in the body-side recess is formed on the lower surface of the cover member, and
at least one of the body-side recess and the cover-side recess is formed in a bowl shape having an inclined surface extending along a radial direction of the stage body.

2. The stage of claim 1, wherein the positional deviation preventing member has a curved surface that makes contact with the inclined surface.

3. The stage of claim 2, wherein the positional deviation preventing member is configured to roll or slide along the inclined surface.

4. The stage of claim 3, wherein the positional deviation preventing member has a true spherical shape, an ellipsoidal shape, or a rounded rectangular shape in a side view.

5. The stage of claim 1, wherein the positional deviation preventing member is configured to roll or slide along the inclined surface.

6. The stage of claim 1, wherein the positional deviation preventing member has a true spherical shape, an ellipsoidal shape, or a rounded rectangular shape in a side view.

7. A substrate processing apparatus comprising the stage of claim 1.

8. The apparatus of claim 7, wherein through-holes vertically penetrate the stage body, and the apparatus further comprises:
substrate support pins inserted through the through-holes and configured to be able to protrude from the upper surface of the stage body through the through-holes; and
a pin support member configured to be able to support the substrate support pins,
wherein the pin support member is attached to the cover member.

9. The apparatus of claim 8, further comprising:
a processing container in which the stage is arranged,
wherein the cover member is configured to divide an inside of the processing container into a space above the stage body and a space below the stage body.

10. The apparatus of claim 7, further comprising:
a processing container in which the stage is arranged,
wherein the cover member is configured to divide an inside of the processing container into a space above the stage body and a space below the stage body.

11. A stage assembling method for assembling a stage on which a substrate is mounted,
wherein the stage includes a stage body having an upper surface on which the substrate is mounted, a cover member configured to cover an outer edge portion of the upper surface of the stage body, and a positional deviation preventing member provided between the upper surface of the stage body and a lower surface of the cover member and configured to roll or slide,
a body-side recess configured to accommodate the positional deviation preventing member is formed on the upper surface of the stage body,
a cover-side recess configured to accommodate the positional deviation preventing member accommodated in the body-side recess is formed on the lower surface of the cover member, and
at least one of the body-side recess and the cover-side recess is formed in a bowl shape having an inclined surface extending along a radial direction of the stage body,
the method comprising:
assembling the stage body and the cover member with each other so that one side portion of the positional deviation preventing member is accommodated in the body-side recess of the stage body and an other side portion of the positional deviation preventing member is accommodated in the cover-side recess of the cover member.
